(19) United States
(12) Patent Application Publication
(10) Pub. No.: US 2024/0426875 A1
(43) Pub. Date: Dec. 26, 2024

(54) A POWER ANALYZER FOR MAINS SWITCHGEAR

(71) Applicant: SMARTE TEKNOLOJI VE ENERJI SANAYI TICARET ANONIM SIRKETI, Istanbul (TR)

(72) Inventors: Melih BALLIKAYA, Istanbul (TR); Selman GUNAY, Istanbul (TR); Recep CELIKKAYA, Istanbul (TR); Naghi SOTOUDEH, Istanbul (TR)

(73) Assignee: SMARTE TEKNOLOJI VE ENERJI SANAYI TICARET ANONIM SIRKETI, Istanbul (TR)

(21) Appl. No.: 18/692,950

(22) PCT Filed: Sep. 17, 2021
(86) PCT No.: PCT/TR2021/050956

§ 371 Date: Mar. 18, 2024

(51) Int. Cl. G01R 15/20; G01R 19/25; G01R 21/133

(52) U.S. Cl. CPC G01R 15/207; G01R 19/25; G01R 21/133

(57) ABSTRACT

A power analyzer for mains switchgear includes a main body, at least one housing which is formed on the main body, suitable for inserting the respective cable of the mains switchgear, and a magnetic sensor provided on the main body for measuring a magnetic field value present in the housing when the respective cable of the mains switchgear is inserted into the housing.

### CROSS REFERENCE TO THE RELATED APPLICATIONS

This application is the national phase entry of International Application No. PCT/TR2021/050956, filed on Sep. 17, 2021, the entire contents of which are incorporated herein by reference.

### TECHNICAL FIELD

The present invention relates to a power analyzer which is suitable to use on the mains switchgear.

### BACKGROUND

A power analyzer is the equipment which used to monitor the electrical parameters of the mains switchgear. Power analyzers can be used to measure the flow of energy in either alternating current (AC) or direct current (DC) systems. The power analyzer in the state of the art, the current value is determined by a current sensor. When the current value is determined by only one sensor, the measurement precision of the current value is decreased.

A prior art publication in the technical field of the invention may be referred to as EP3384576 (A1), which discloses a power analyzer.

The invention provides an additional improvement to the prior art.

### SUMMARY

An object of the present invention is to determine the current value which flows in the cable of the mains switchgear in an accurate manner.

The present invention proposes a power analyzer for mains switchgear comprising, a main body, at least one housing which is formed on the main body, suitable for inserting the respective cable of the mains switchgear, a magnetic sensor provided on the main body for measuring a magnetic field value present in the housing when the respective cable of the mains switchgear is inserted into the housing. The power analyzer comprises a position sensor is provided on the main body for determining a distance value between the cable and the magnetic sensor and a control unit that is configured to calculate the current value which flows in the cable by using the distance value and the magnetic field value. A position sensor is a sensor that facilitates measurement of mechanical position. A position sensor may indicate absolute position (location) or relative position (displacement), in terms of linear travel, rotational angle, or three-dimensional space. The position sensor may be a capacitive displacement sensor or a differential capacitive sensor or an eddy current sensor or a laser sensor or a photodiode array or a hall effect sensor or an inductive sensor or an infrared sensor or a piezo-electric transducer or a position encoder or an ultrasound sensor or a RGB color space sensor or a time-of-flight sensor or an optical sensor or a camera or a stereo-camera or a lidar. The distance between the magnetic sensor and the outer surface of the cable can be determined by the position sensor. Since the magnetic sensor is fixed on the main body, the distance can be determined by the control unit after the cable position is determined by the position sensor. Moreover, detection of the presence or absence of the cable in the housing can be determined by means of the position sensor. The magnetic sensor may be an inductive sensor. In the preferred embodiment of the present invention, the magnetic sensor is a hall effect sensor. The magnetic sensor measures the value of the magnetic field which is created by the cable wherein the current flows. The control unit calculates the current value which flows in the cable by using the magnetic field value and the distance value. Since the distance between the outer surface of the cable and the magnetic sensor, and the value of the magnetic field which affects the magnetic sensor are determined in an accurate way, the current value can be calculated accurately by the control unit. The control unit is configured to calculate the current value continuously or periodically. Thus, the current value flowing in the cable is determined continuously.

In a possible embodiment, the power analyzer comprises the housing having two opposite side walls and a bottom wall. The housing is not surrounded by the walls in order to make it easier to be inserted cable into the housing. Besides, the cable is removed from the housing easily.

In a possible embodiment, the position sensor is an optical sensor. The optical sensor has a transmitter which is provided on the side wall and a receiver which provided on the opposite side wall to sense the light. More than one transmitter and receivers can be provided on the side walls in order to increase the measurement precision. Thus, cable position in the housing or the distance between the outer surface of the cable and the magnetic sensor is determined by the optical sensor precisely.

In a possible embodiment, the magnetic sensor is provided on the main body so as to be under the bottom wall of the housing. The magnetic sensor is fixed the under surface of the bottom wall so as to be in the main body. Thus, the distance value between the magnetic sensor and the outer surface of the cable equals to sum of the thickness value of the bottom wall and distance value between the outer surface of the cable within the housing and bottom wall. In this case, the distance between the bottom wall and the outer surface of the cable is determined by the position sensor. Then the control unit calculates the distance value between the outer surface of the cable and the magnetic sensor by adding the thickness value to the data which is collected by the position sensor. In a preferred embodiment of the present invention, the position sensor is calibrated by adding the thickness value to the data in order to determine the distance value between the outer surface of cable in the housing and magnetic sensor. Thus, the magnetic sensor is kept closer to the cable while the magnetic sensor is protected from being damaged by the environmental factors.

In a possible embodiment, at least one side wall is provided with a cable holder. The cable holder is made of an elastic material. Thus, the cable is fixed between the side walls while the outer surface of the cable is prevented from damaging.

In a possible embodiment, the main body comprises three housings. Thus, the power analyzer can be used on the three-phase type switchgears.

In a possible embodiment, the power analyzer comprises a wireless communication module. The wireless communication module can be a Wi-Fi or Bluetooth or any commercial radio communication type. The wireless communication module communicates with the mobile phone or computer. Thus, the user monitors the parameters of the power analyzer. Besides, the power analyzer is controlled remotely by the user.

In a possible embodiment, the power analyzer comprises a voltage sensing means which is adapted to collect a voltage signal from the mains switchgear for measuring the voltage value of the mains switchgear. Consumed electrical power value is calculated by multiplying the voltage value which is determined by the voltage sensing means and the current value which is calculated by the control unit. Thus, the quality of the voltage is determined. Besides, the power value is determined precisely.

In a possible embodiment, the power analyzer comprises at least three voltage sensing means which are connected to the main body. Three voltage sensing means are connected respective pins of the three-phase type switchgear. Thus, the power analyzer which can be used on the three-phase type switchgear is realized.

In a possible embodiment, the voltage sensing means are detachably attached each other. Thus, a compact block which is constructed by more than one voltage sensing means is realized.

In a possible embodiment, the voltage sensing means has an outer body which is provided with a protrusion and a corresponding recess, both of the protrusion and the recess are being sized and shaped to engage each other when the voltage sensing means are attached each other. Thus, the voltage sensing means are connected each other in a form-fit manner.

In a possible embodiment, the control unit is configured to generate a warning signal when the control unit determines that the position of the cable in the housing is changed. Thus, the user is informed about the cable position in the housing immediately.

In a possible embodiment, a display is used for displaying at least one parameter which is determined by the control unit. The display is provided on the main body. Thus, the user is informed about the parameters continuously.

### BRIEF DESCRIPTION OF THE DRAWINGS

The accompanying drawings are given solely for the purpose of exemplifying the invention whose advantages over prior art were outlined above and will be explained in detail hereinafter:

FIG. 1 is a perspective view of the power analyzer when the power analyzer is connected to the mains switchgear.

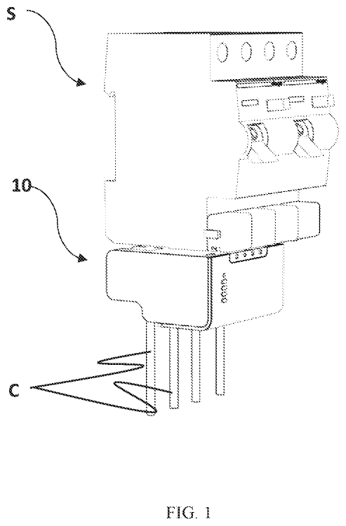

FIG. 2 is a perspective view of the power analyzer.

FIG. 3 is a schematic view of the power analyzer.

FIG. 4 is a schematic view of the power analyzer having two cable holders.

FIG. 5 is a schematic view of the power analyzer with four voltage sensing means.

FIG. 6 is a schematic view of the power analyzer with four voltage sensing means.

### DETAILED DESCRIPTION OF THE EMBODIMENTS

The present invention proposes a power analyzer (10) for mains switchgear(S) comprising, a main body (20), at least one housing (21) which is formed on the main body (20), suitable for inserting the respective cable (C) of the mains switchgear(S), a magnetic sensor (30) provided on the main body (20) for measuring a magnetic field value present in the housing (21) when the respective cable (C) of the mains switchgear (S) is inserted into the housing (21). When a current flows in a cable (C), it creates a circular magnetic field around the cable (C). The magnetic sensor (30) measures the magnetic field value. The power analyzer (10) also comprises a position sensor (40) is provided on the main body (20) for determining a distance value between the cable (C) and the magnetic sensor (30) and a control unit (50) that is configured to calculate the current value which flows in the cable (C) by using the distance value and the magnetic field value. The strength of the magnetic field is greater closer to the cable (C), and increases if the current increases. The magnetic field value of the position at a distance of “r” from the outside surface of the cable (C) wherein the current flows is calculated by the formula which is given in Equation 1.

$$B = \frac{{μ}_{0} I}{2 π r} \qquad ( Equation 1 )$$

In Equation 1; “I” corresponds to current value in Amperes (A), “B” corresponds to magnetic field value in Tesla (T) and “r” corresponds to the distance from the outer surface of the cable in meters (m). μ₀ refers to the permeability of free space. μ₀ is a constant value and equals to 4π10⁻⁷T·m/A. As can be deducted from the Equation 1, the distance between the cable (C) and the magnetic sensor (30) is crucial for determining the magnetic field value accurately. The position sensor (40) is used for determining the cable (C) position in the housing (21) and/or determining distance between the cable (C) and the magnetic sensor (30). The position sensor (40) can also determine the diameter of the cable (C) which is positioned in the housing (21). Besides, position changes of the cable (C) in the housing (21) can be detected by means of the position sensor (40). When the cable (C) position is changed within the housing (21), the magnetic field value determined by the magnetic sensor (30) is changed. The control unit (50) is adapted to calculate the current value flowing in the cable (C) by using the magnetic field value and the distance between cable (C) and the magnetic sensor (30). In the preferred embodiment of the present invention, the control unit (50) is configured to calculate the current value as in Equation 1. Thus, the current value which flows in the cable (C) is determined accurately even if the cable (C) position is changed within the housing (21).

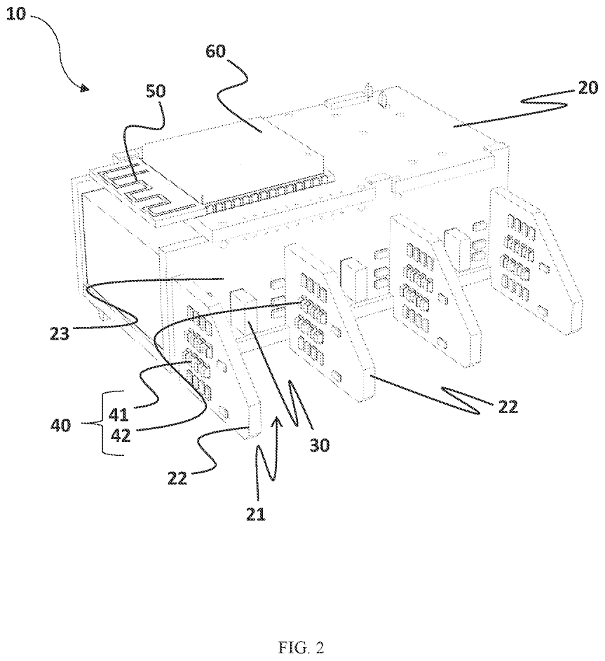

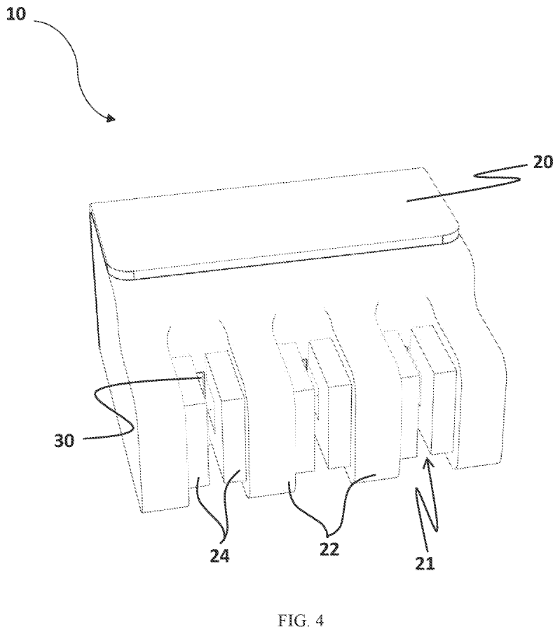

In an embodiment of the present invention, the housing (21) has two opposite side walls (22) and a bottom wall (23). As can be seen in the FIGS. 2-4, the housing (21) is in the form of U-shaped. At least one portion of the cable (C) is inserted into the housing (21) so as to be between the side walls (22). Thus, the power analyzer (10) is attached to the cable (C) of the mains switchgear (S) easily.

In an embodiment of the present invention, the position sensor (40) is an optical sensor. Optical sensors operate using one of two principles. In the first type, the emitted light signal is reflected from the object being monitored returned towards the light source. A change in the light characteristics (e.g. wavelength, intensity, phase, polarization) is used to establish information about the object's position. Thus, the position of the cable (C) in the housing (21) is determined by using the data which is collected from the optical sensor.

In the second type, light is transmitted from a transmitter (41) and sent over to a receiver (42) at the other end of the optical sensor. Referring to FIG. 2, the transmitter (41) is provided on the side wall (22) and the receiver (42) is provided on the opposite side wall (22) to sense the light. When at least one portion of the cable (C) is inserted into the housing (21) so as to be between the side walls (22), some lights transmitted from the transmitter (41) are not received by the receiver (42). Thus, the position and the diameter of the cable (C) is determined in an accurate manner.

Referring to FIGS. 2-4, the magnetic sensor (30) is provided on the bottom wall (23) of the housing (21). The magnetic sensor (30) is placed on the bottom wall (23) so as to be flush with the upper surface of the bottom wall (23), which faces the housing (21). In this construction, a sensor housing is provided on the bottom wall (23) and the magnetic sensor (30) is placed in the sensor housing. Therefore, the distance between the bottom wall (23) and the outer surface of the cable (C) equals to the distance between the magnetic sensor (30) and the outer surface of the cable (C). Thus, determining the current value is made easier and the precision of the calculation is increased.

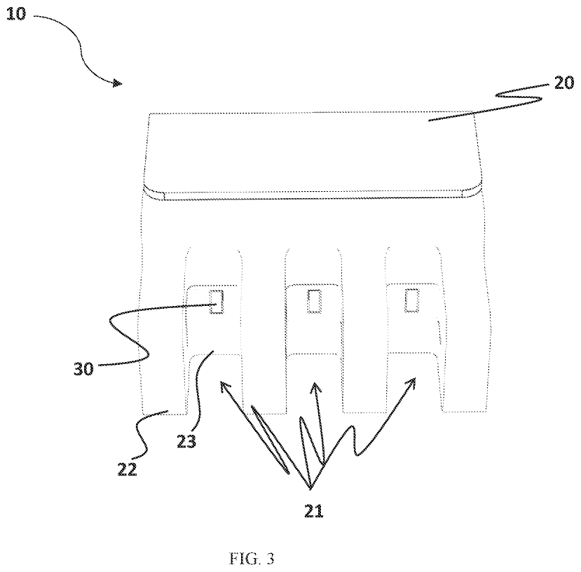

In an embodiment of the present invention, at least one side wall (22) is provided with a cable holder (24). As can be seen in FIG. 3, the cable (C) is connected to the side wall (22) by means of the cable holder (24). The cable (C) is removably connected to the cable holder (24). In the preferred embodiment of the invention disclosure, each side walls (22) are provided with a cable holder (24). The cable (C) is squeezed by the cable holders (24). Thus, the cable (C) is protected from moving unintentionally.

In another embodiment of the present invention, the main body (20) comprises three housings (21). The mains switchgear (S) may be a three-phase type. Therefore, respective cables (C) for each phase of the mains switchgear (S) are inserted into the respective housings (21). Thus, the power analyzer (10) can be used for determining the current values of three-phase type mains switchgear (S). These housings (21) are formed on the main body (20) side by side.

In another embodiment of the present invention, a wireless communication module (60) is provided on the main body (20). The wireless communication module (60) may be provided on the control unit (50). Thus, the power analyzer (10) transmits the data which is collected by the magnetic sensor (30) and/or position sensor (40) and/or calculated by the control unit (50) to the outside management or data storage device.

In another embodiment of the present invention, the power analyzer (10) comprises a voltage sensing means (70) which is adapted to collect a voltage signal from the mains switchgear (S) for measuring the voltage value of the mains switchgear (S) and the control unit (50) is adapted to calculate power value by multiplying the voltage value and the current value. The voltage sensing means (70) is connected to the main body (20) of the power analyzer (10) via a conductor. Voltage sensing means (70) has at least one voltage probe (74) which is suitable to insert respective pins of the mains switchgear (S). In the preferred embodiment of the present invention, the voltage sensing probe (74) is provided with a magnetic material in order to connect the voltage sensing probe (74) and the respective pins of the mains switchgear (S). Voltage sensing means (70) is attached to the respective pins of the mains switchgear (S). The control unit (50) is adapted to calculate the power value by using the current value which is calculated by the control unit (50) and the voltage value which is measured by the voltage sensing means (70). The power value is the rate, per unit time, at which electrical energy is transferred by an electric circuit. For any circuit element, the power value is equal to the voltage difference across the element multiplied by the current value. Thus, the power value is determined by the power analyzer (10). The power value is calculated in terms of Watt.

In another embodiment of the present invention, at least three voltage sensing means (70) are connected to the main body (20). Thus, the power analyzer (10) can be used in three-phase type mains switchgear (S). In the preferred embodiment of the present invention, four voltage sensing means (70) are used for determining the voltage value of the mains switchgear (S). Three of these voltage sensing means (70) are used for the three-phase and the fourth voltage sensing means (70) is used for grounding.

In an embodiment of the present invention, the voltage sensing means (70) are detachably attached each other. The cable (C) layout of the mains switchgear (S) is not the same for every mains switchgear (S). Since the voltage sensing means (70) are detachably attached each other, the layout of the voltage sensing means (70) can be arranged for being used on the mains switchgears(S) having different cable (C) layout.

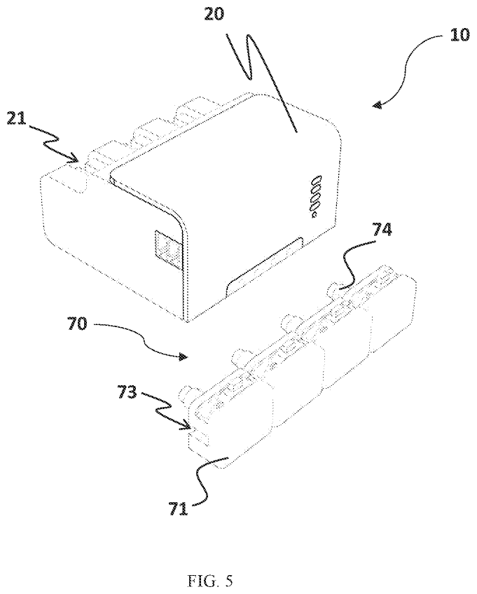

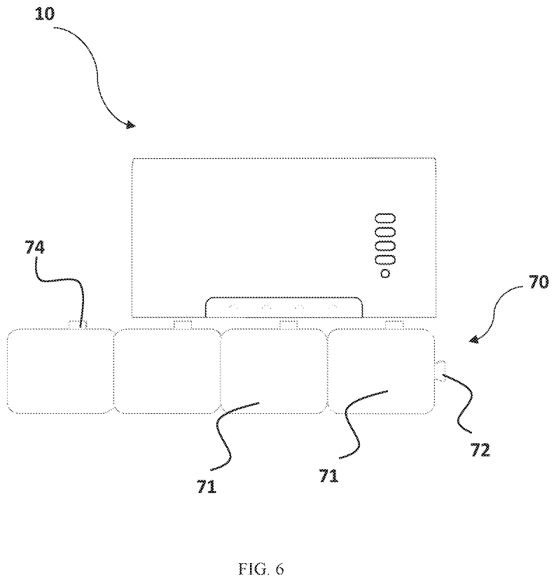

Referring to FIGS. 5-6, the voltage sensing means (70) has an outer body (71) which is provided with a protrusion (72) and a corresponding recess (73), both of the protrusion (72) and the recess (73) are being sized and shaped to engage each other when the voltage sensing means (70) are attached each other. In the preferred embodiment of the present invention, each outer body (71) of the voltage sensing means are same. As can be seen in FIG. 5, the outer body (71) is provided with a recess (73) on the left side of the outer body (71). As can be seen in FIG. 6, the outer body (71) is provided with a protrusion (72) on the right side of the outer body (71). Thus, these two voltage sensing means (70) can be connected to each other side by side by means of the protrusion (72) and the recess (73). When the user wants to change the position of the voltage sensing means (70) with respect to each other, the user separates the protrusion (72) of the first voltage sensing means (70) from the recess (73) of the second voltage sensing means (70) and the user inserts the protrusion (72) of the second voltage sensing means (70) into the recess (73) of the first voltage sensing means (73). Thus, the voltage sensing means (70) are connected each other in a form-fit manner.

In another embodiment of the present invention, the control unit (50) is configured to generate a warning signal when the control unit (50) determines that the position of the cable (C) in the housing (21) is changed. The warning signal can be an audio warning or a visual warning. The control unit (50) determines that the position of the cable (C) in the housing (21) according to the data which is obtained by the position sensor (40). When the position of the cable (C) in the housing (21) is changed, the control unit (50) generates a warning signal for the user. Thus, the user recognizes the changing position of the cable (C) in the housing (21). Moreover, another warning signal can be generated for the user if the control unit (50) detects the absence of the cable (C) in the housing (21). Absence of the cable (C) can be determined by the position sensor (40) or magnetic sensor (30).

In another embodiment of the present invention, a display is used for displaying at least one parameter which is determined by the control unit (50). The display is electrically connected to the power analyzer (10). Thus, monitoring of the parameters is made easier.

### REFERENCE NUMBERS

10. Power analyzer
20. Main body
   21. Housing
   22. Side wall
   23. Bottom wall
   24. Cable holder
30. Magnetic sensor
40. Position sensor
   41. Transmitter
   42. Receiver
50 Control unit
60. Wireless communication module
70. Voltage sensing means
   71. Outer body
   72. Protrusion
   73. Recess
   74. Voltage sensing probe

What is claimed is:

1. A power analyzer for a mains switchgear comprising,
a main body,
at least a housing formed on the main body, wherein the housing is suitable for inserting a respective cable of the mains switchgear,
a magnetic sensor, wherein the magnetic sensor is provided on the main body for measuring a magnetic field value present in the housing when the respective cable of the mains switchgear is inserted into the housing, wherein
a position sensor is provided on the main body for determining a distance value between the respective cable and the magnetic sensor, and
a control unit is configured to calculate a current value flowing in the respective cable by using the distance value and the magnetic field value.

2. The power analyzer according to claim 1, wherein the housing has two opposite side walls and a bottom wall.

3. The power analyzer according to claim 1, wherein the position sensor is an optical sensor.

4. The power analyzer according to claim 3, wherein the optical sensor has a transmitter provided on a first one of the two opposite side walls and a receiver provided on a second one of the two opposite side walls to sense a light.

5. The power analyzer according to claim 2, wherein the magnetic sensor is provided on the bottom wall of the housing.

6. The power analyzer according to claim 2, wherein at least one of the two opposite side walls is provided with a cable holder.

7. The power analyzer according to claim 1, wherein the main body comprises three housings.

8. The power analyzer according to claim 1, wherein a wireless communication module is provided on the main body.

9. The power analyzer according to claim 1, wherein voltage sensing means are adapted to collect a voltage signal from the mains switchgear for measuring a voltage value of the mains switchgear and the control unit is adapted to calculate a power value by multiplying the voltage value and the current value.

10. The power analyzer according to claim 9, wherein at least three voltage sensing means are connected to the main body.

11. The power analyzer according to claim 9, wherein the voltage sensing means are detachably attached each other.

12. The power analyzer according to claim 11, wherein each of the voltage sensing means has an outer body provided with a protrusion and a corresponding recess, both of the protrusion and the corresponding recess are being sized and shaped to engage each other when the voltage sensing means are attached each other.

13. The power analyzer according to claim 1, wherein the control unit is configured to generate a warning signal when the control unit determines that a position of the respective cable in the housing is changed.

14. The power analyzer according to claim 1, wherein a display is configured for displaying at least one parameter, the at least one parameter is determined by the control unit.

15. The power analyzer according to claim 2, wherein the position sensor is an optical sensor.

16. The power analyzer according to claim 3, wherein the magnetic sensor is provided on a bottom wall of the housing.

17. The power analyzer according to claim 4, wherein the magnetic sensor is provided on a bottom wall of the housing.

18. The power analyzer according to claim 3, wherein at least one of two opposite side walls is provided with a cable holder.

19. The power analyzer according to claim 4, wherein at least one of the two opposite side walls is provided with a cable holder.

20. The power analyzer according to claim 5, wherein at least one of the two opposite side walls is provided with a cable holder.
